(19) United States
(12) Patent Application Publication
(10) Pub. No.: US 2026/0080138 A1
(43) Pub. Date: Mar. 19, 2026

(54) System for Correction of Circuit Verification Code

(71) Applicant: ChipStack Inc, Seattle, WA (US)

(72) Inventors: Chandra Bhagavatula, Seattle, WA (US); Ryan Eiger, Seattle, WA (US); Javad Ghasemi, San Jose, CA (US); Shivang Ghetia, San Jose, CA (US); Ross Harding, Seattle, WA (US); Kartik Hegde, Seattle, WA (US); Joseph Miller, San Jose, CA (US); Hamid Shojaei, San Jose, CA (US); Vineet Thumuluri, San Jose, CA (US); Artem Bakalov, Seattle, WA (US); Dipayan Saha, Gainesville, FL (US)

(21) Appl. No.: 18/890,484

(22) Filed: Sep. 19, 2024

(51) Int. Cl. G06F 30/3308; G06F 30/31; G06N 3/045; G06N 3/08

(52) U.S. Cl. CPC G06F 30/3308; G06F 30/31; G06N 3/045; G06N 3/08

(57) ABSTRACT

A system generates verification code for a circuit design, such as a circuit design specified in RTL. An RTL file and specification are parsed to obtain ports, design parameters, and other functionality of the circuit design. The parsed RTL file and specification are processed by an LLM to generate a model including descriptions of the ports, design parameters, basic functionality, end-to-end functionality, corner-case scenarios and error scenarios. The model is processed by an LLM to generate a test plan that is processed by an LLM to generate verification code, such as simulation unit tests or formal verification assertions. The verification code may be revised by an LLM to correct syntax errors, improve performance, generate helper assertions, or generate auxiliary logic.

### FIELD OF THE INVENTION

This invention relates to the generation of test code for verifying a circuit design.

### BACKGROUND OF THE INVENTION

Field programmable gate arrays (FPGA), application specific integrated circuits (ASIC), and other types of circuits are very complex. Often, such circuits are designed using a specialized programming language, such as a register transfer language (RTL). Example RTLs include VERILOG, VHSIC hardware description language (VHDL), and other hardware generation languages (HGL).

A design specified using an RTL may be compiled and tested using electronic design automation (EDA) software prior to investing in the fabrication of a physical circuit.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 illustrates a system for the automatic generation of verification code for testing circuit designs in accordance with an embodiment of the present invention;

FIG. 2 is a process flow diagram of a method for generating a model of a circuit design in accordance with an embodiment of the present invention;

FIG. 3 is a schematic diagram of a circuit design hierarchy in accordance with an embodiment of the present invention;

FIG. 4 is schematic diagram of a model of circuit design code in accordance with an embodiment of the present invention;

FIGS. 5A and 5C illustrate the training of large language models (LLM) to generate unit verification code in accordance with an embodiment of the present invention;

FIGS. 6A and 6B illustrate the training of large language models (LLM) to generate formal verification assertions in accordance with an embodiment of the present invention;

FIG. 7 illustrates a system for training an LLM to generate error-producing code for generating synthetic training data in accordance with an embodiment of the present invention;

FIG. 8 is a process flow diagram of a method for using an LLM to generate error-producing code for generating synthetic training data in accordance with an embodiment of the present invention;

FIGS. 9A and 9B illustrate training an LLM to correct and improve verification code in accordance with an embodiment of the present invention;

FIG. 10 illustrates using EDA software to train an LLM in accordance with an embodiment of the present invention;

FIG. 11 is a process flow diagram of a method for correcting verification code using an LLM in accordance with an embodiment of the present invention;

FIG. 12 is a process flow diagram of a method for verifying circuit design code using verification code in accordance with an embodiment of the present invention;

FIG. 13 illustrates training an LLM to perform a chat function with respect to circuit design code and verification code in accordance with an embodiment of the present invention;

FIG. 14 illustrates training a correction LLM in accordance with an embodiment of the present invention;

FIG. 15 illustrates a system for using a correction LLM in accordance with an embodiment of the present invention;

FIG. 16 illustrates an approach for generating synthetic training data in accordance with an embodiment of the present invention; and

FIG. 17 is a schematic block diagram illustrating an example computing device suitable for implementing methods in accordance with embodiments of the present invention.

### DETAILED DESCRIPTION

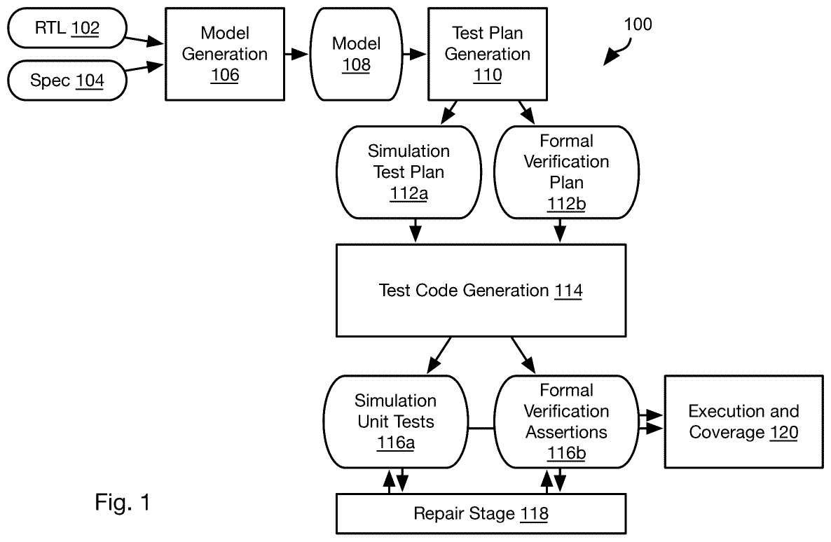

Referring to FIG. 1, the illustrated system 100 may be used to generate verification code for verifying a circuit design, such as a circuit design specified in a register transfer language (RTL) file 102. The RTL file 102 may be a file containing VERILOG or other hardware generation language (HGL) code. The RTL file 102 may be linked to multiple other RTL files 102, such as a library of circuit designs. A circuit design may be for an application specific integrated circuit (ASIC) or define the configuration of a field programmable gate array (FPGA) or other type of programmable circuit device.

The system 100 may further receive a specification 104 corresponding to the RTL file 102. The specification 104 may be a natural language description of the functionality performed by the RTL code in the RTL file 102. The specification 104 may, for example, be natural language documentation for a user of the RTL file 102.

The RTL file 102 and specification 104 may be processed using a model generation stage 106 to obtain a model 108 of the RTL file 102. The model 108 may be processed using a test plan generation stage 110 to obtain a test plan for verifying the design defined by the RTL file 102. The test plan may include a simulation test plan 112a or a formal verification plan 112b. The simulation test plan 112a and/or formal verification plan 112b may be input to a test code generation stage 114. The test code generation stage 114 may output simulation unit tests 116a based on the simulation test plan 112a. The test code generation stage 114 may output formal verification assertions 116b for the formal verification plan 112b. The simulation unit tests 116a and formal verification assertions 116b may include executable code, such as RTL code that may be executed by circuit design software to perform tests or formal verification.

The system 100 may include a repair stage 118. The repair stage may be configured to repair syntax, semantic, logical, performance-reducing, or other errors present in the automatically generated simulation unit tests 116a and formal verification assertions 116b. The simulation unit tests 116a and formal verification assertions 116b may be executed, such as by EDA software. The results of processing may be processed by an execution and coverage stage 120, which generates a report showing the results of testing, coverage of the design in the RTL file 102, and possibly other information. The output of the execution and coverage stage may be used to improve the outputs of any of the preceding stages, such as the test plan generation stage 110 and test code generation stage 114. In particular, error codes, insufficient coverage, or other errors relating to the test code itself may be used as feedback for repeated application of the functionality of the test plan generation stage 110 and test code generation stage 114.

The operation of the various stages of the system 100 will be described in greater detail below.

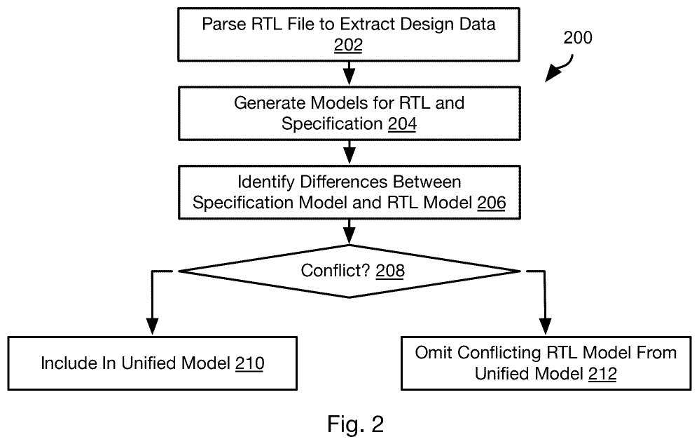

FIGS. 2, 3, and 4 illustrate the operation of the model generation stage 106. Referring specifically to FIG. 2, a method 200 may include parsing 202 the RTL file 102 to extract design data. The design data may include ports, parameters, a design hierarchy, or other information. The ports may include inputs to a circuit, outputs from a circuit, inputs or outputs of a module internal to a circuit, or the like. Parameters may include tunable values that define the design, such as a depth of a queue, a width (number of bits) of a variable, a number of instances of a module (e.g., processor core), a number of threads, or the like. A design hierarchy may include references to instantiation of modules of a circuit design, e.g., what modules are instantiated and by which other modules. A module may be a circuit specified by an RTL file incorporated into the RTL file 102, such as from a library. For example, a first module may be an entity in the hierarchy with children of the first module being second modules instantiated by the first module.

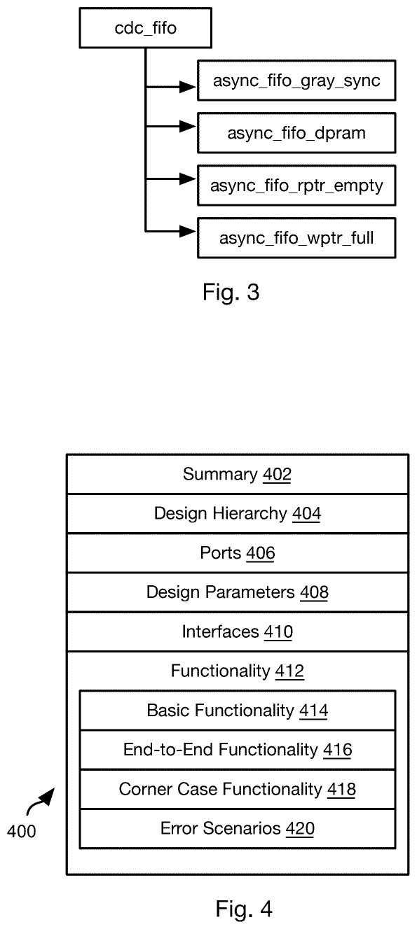

For example, referring to FIG. 3, a design hierarchy for a first in first out (FIFO) buffer may include a root module representing the FIFO buffer (cdc_fifo). Children of the root module may include an asynchronous interface to the buffer (async_fifo_gray_sync), an asynchronous memory (e.g., dual port random access memory (DPRAM) for storing data input to the buffer (async_fifo_dpram), an interface for determining when the buffer is empty (async_fifo_rptr_empty), and an interface for determining when the buffer is full (async_fifo_wptr_full).

The method 200 may include generating 204 a model of the RTL file 102 and a model of the specification 104. In some instances, a specification 104 is not present such that only a model of the RTL file 102 is generated 204.

A model of the RTL file 102 or specification 104 may include a logical description of the functionality of the circuit design encoded in the RTL file 102 or specification, respectively. For example, referring to FIG. 4, a model 400 may include a summary 402 that is a natural language description of an overall function of the circuit design included in the RTL file 102 or specification, such as with reference to input and output ports of the circuit design. The model 400 may include a design hierarchy 404 as described above.

The model 400 may include the ports 406 identified from the parsing of step 202. The model 400 may include a natural language description of the function associated with data input through the port according to the RTL File 102 or specification 104.

The model 400 may include the design parameters 408 obtained from the parsing 202. The model 400 may include a natural language description of the function of each design parameter 408, a range of acceptable values for each design parameters, or other descriptive data.

The model 400 may include interfaces 410 of the circuit design described by the RTL file 102. Interfaces 410 may include a description of control words, timing, signal inputs and/or outputs, functionality associated with logical values (binary 1 or 0), or other features describing how circuit design is configured to interface with another entity.

The model 400 may include a natural language description of the functionality 412 of the circuit design included in the RTL file. For example, the functionality 412 may include a description of basic functionality 414, which is a high-level description of the function performed by the circuit design in the RTL file 102 or specification 104.

The natural language description of the functionality 412 may include a natural language description of end-to-end functionality 416 of the circuit design in the RTL file 102 or specification 104. For example, the description may describe calculations, decisions (if, else), loops, movement of data, or other functions beginning with input data on an input port and ending with corresponding output data at an output port.

The natural language description of the functionality 412 may include a natural language description of corner case functionality 418. Corner case functionality may include scenarios in terms of inputs, outputs, or intermediate results for which the circuit design transitions from one mode of operation to another or is at an extreme state of operation.

The natural language description of the functionality 412 may include a natural language description of error scenarios 420. Error scenarios may include recognized scenarios (e.g., inputs, or co-occurrence of inputs) that are not permitted and for which the circuit design will not produce a valid output.

In some embodiment, generating 204 the model may include using a template including entries for each of the items 402-420 shown in FIG. 4 and supplying information for each of the entries.

Referring again to FIG. 2, the method 200 may include identifying 206 differences exist between a model generated at step 204 for the RTL file 102 (“the RTL model”) to the model generated at step 204 for the specification 104 (“the specification model”). A unified model may then be generated based on the comparison. For example, the unified model may be the specification model modified as described below with respect to steps 206-212.

For example, for each difference identified, at step 206, the method 200 may include evaluating 208 whether the difference is conflicting. For example, if a portion of the RTL model is different from a corresponding portion of the specification model, then only the portion of the specification model will be included in the unified model and the conflicting portion of the RTL model will be omitted from the unified model. Portions may be deemed to correspond to one another if they are different and describe the same port, variable, or other entity. This approach may have the advantage of adhering to the intent of the designer and enable the detection of any defects in the RTL file 102 that do not conform that that intent. If the difference includes a portion that is included in the RTL model that is not present in the specification model and that is not found 208 to conflict with a portion of the specification model, the portion may be included 212 in the unified model. 4.

Differences between the models for the RTL file 102 and the specification 104 may be reported, such as to a user that submitted to the RTL file 102 and specification 104. For example, the differences may be reported in a log file, output to a display device, transmitted to user device, or otherwise communicated to a user. For example, parts of the RTL model that are different from the specification model may be reported to the user as potential defects in the RTL file 102.

The unified model generated at step 206 may be the model 108 output by the model generation stage 106. In embodiments where only one of the RTL file 102 and specification 104 are used, only one model may be generated and used as the output of the model generation stage 106 and steps 206-212 may be eliminated.

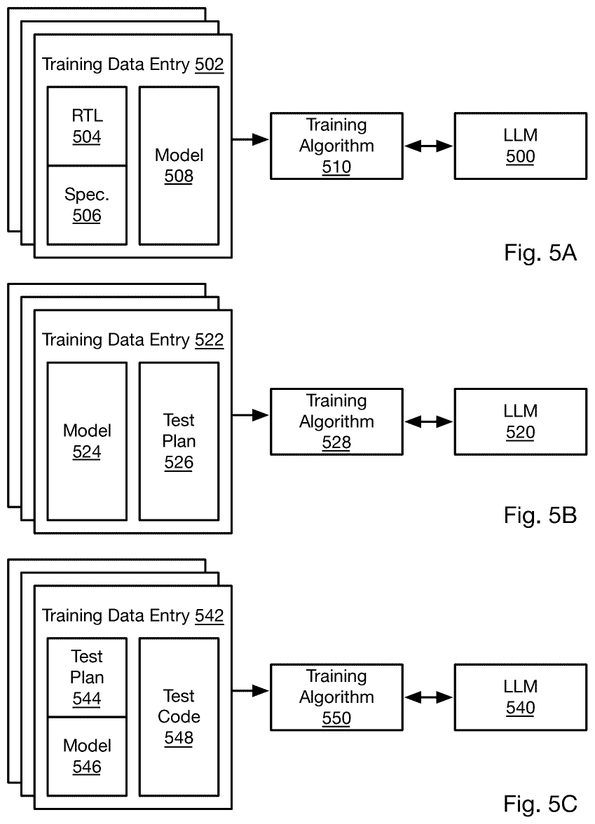

FIGS. 5A, 5B, and 5C illustrate example approaches for implementing the model generation stage 106, test plan generation stage 110, and test code generation stage 114.

Referring specifically to FIG. 5A, step 204 of the method 200 may be performed using an LLM 500 trained using the illustrated approach. For example, step 204 may include submitting the parsed RTL file 102 and the specification 104 to the LLM 500 with a prompt to generate a model based on the parsed RTL file. The prompt may include examples, e.g., an example parsed RTL file, an example specification, and an example model generated based on the parsed example RTL file and the example specification. The example model may be human-generated or automatically generated and verified by a human reviewer.

The LLM 500 may be a general LLM, such as OPEN AI CHATGPT, GOOGLE GEMINI, or other type of LLM. As used herein a general LLM is trained to response to prompts on many topics, including those that do not involve circuit design.

In some embodiments, the LLM 500 may be a specific LLM trained to perform one or more tasks relating to the automatic generation of test code for testing a circuit design. For example, the LLM 500 may be trained with training data entries 502 that each include, as an input, a parsed RTL file 504 and a specification 506 and, as a desired output, a model 508, e.g., a model 400, corresponding to the input. The model 508 may be human-generated or generated by an LLM and verified and/or revised by a human reviewer.

A training algorithm 510 may prompt the LLM 500 with the input from each training data entry 502, receive an output from the LLM 500 in response to the prompt, compare the output from the LLM 500 with the output from the training data entry 502, and provide feedback to the LLM 500 according to the comparison. The prompt to the LLM 500 may include an instruction to generate a model based on the input and may include an example as described above. The training algorithm 510 and any of the other training algorithms described herein may implement custom loss functions and optimization algorithms.

During utilization, the trained LLM 500 is prompted with an RTL file and/or a specification, the prompt requesting that the LLM 500 generate a model. The output of the LLM 500 in response to the prompt may then be used as the model 108 in subsequent processing by the system 100.

Referring to FIG. 5B, an LLM 520 may be trained to implement the test plan generation stage 110. For example, an LLM 520 may be trained to generate a simulation test plan 112a and a separate LLM 520 may be trained to generate a formal verification plan 112b. Alternatively, the LLM 520 may be trained to generate both of a simulation test plan 112a and formal verification plan 112b. In either case, the plans 112a,112b describe scenarios to test and a reason why a particular test was generated. The plans 112a, 112b may include design constraints, such as may be specified in the specification 104, test point scenarios, and coverage information.

A simulation test plan 112a may define sequences of inputs to ports of the circuit design (e.g., input data, control signals, clock signals) and expected outputs. The test plan may be designed to provide a desired coverage of the circuit design represented in the RTL file 102 and specification 104. In particular, coverage may be defined as a function of some or all of (a) a percentage of the circuits of the circuit design that are invoked, (b) a percentage of possible input values to the overall circuit design or each circuit of the circuit design that are tested, and (c) a number of states of the circuit design that are reached.

A circuit design may be parameterized (see, e.g., the description of the design parameters 408, above). A simulation test plan 112a may further define a plurality of device under test (DUT) definitions that each define values for the design parameters. The test plan may define a DUT for each possible combination of values for the design parameters or may only generate DUTs for extreme cases (e.g., combinations of maximum and minimum values for the design parameters), average cases (combinations of common values of the design parameters), or other corner cases for the design parameters. A simulation test plan 112a may include test point scenarios, coverage information, and/or design constraints derived from the model 108.

The LLM 520 may be trained using training data entries 522. Each training data entry 522 may include, as an input, a model 524, such as model 400 generated according to the method 200 and, as an output, a test plan 526, which may include one or both of a simulation test plan 112a and formal verification plan 112b. The test plan 526 may be human-generated or automatically generated and verified and/or revised by a human.

A training algorithm 528 may prompt the LLM 520 with the input from each training data entry 522, receive an output from the LLM 520 in response to the prompt, compare the output from the LLM 520 with the output from the training data entry 522, and provide feedback to the LLM 520 according to the comparison. The prompt to the LLM 520 may include an instruction to generate a test plan based on the input and may include an example, e.g., a model and a corresponding human-generated simulation test plan 112a and/or formal verification plan 112b.

During utilization, the trained LLM 520 is prompted with a model, the prompt requesting that the LLM 520 generate a simulation test plan 112a and/or formal verification plan 112b. The output of the LLM 520 in response to the prompt may then be used as a simulation test plan 112a and/or formal verification plan 112b in subsequent processing by the system 100.

Referring to FIG. 5C, an LLM 540 may be trained to implement the test code generation stage 114. For example, an LLM 540 may be trained to generate simulation unit tests 116a, formal verification assertions 116b, or both.

Simulation units tests 116a may include RTL code instantiating a DUT and executing tests with respect to the DUT. The simulation unit tests 116a may include RTL code instantiating a test bench for generating inputs to the DUT and receiving outputs of the DUT. The simulation unit tests 116a may be generated according to the simulation test plan 112a and may include a simulation unit test 116a for each DUT defined according to the test plan 112a.

Formal verification assertions 116b include logical statements that must be true with respect to a plurality of variables, such as inputs, outputs, and one or more internal variables of a circuit design according to the specification 104 and/or RTL file 102.

The LLM 540 may be trained using training data entries 542. Each training data entry 542 may include, as an input, a test plan 544. The test plan 544 may be one or both of a simulation test plan 112a and a formal verification plan 112b. The input of each training data entry 542 may further include a model 546, e.g., a model 400 for which the test plan 544 was generated or that was generated based on the same RTL file 102 and specification 104 as the test plan 544. The test plan 544 may be human-generated or automatically generated and verified and/or revised by a human. The desired output of each training data entry 542 may be test code 548. The test code 548 may be an RTL file or set of RTL files implementing DUTs and corresponding test benches according to a simulation test plan 112a and/or code configured to evaluate a set of assertions according to a formal verification plan 112b. In this embodiment and other embodiments disclosed herein, references to an “assertion” may be understood to be an assertion written in a corresponding language for expressing assertions, such as System VERILOG Assertions (SVA). The test code 548 may be written by a human or automatically generated and revised or verified by a human.

A training algorithm 550 may prompt the LLM 540 with the input from each training data entry 542, receive an output from the LLM 540 in response to the prompt, compare the output from the LLM 540 with the output from the training data entry 542, and provide feedback to the LLM 540 according to the comparison. The prompt to the LLM 540 may include an instruction to generate the test code 548 and may include an example, e.g., a model 400, a test plan generated based on the model 400, and a corresponding human-generated simulation unit tests 116a and/or formal verification assertions 116b.

During utilization, the trained LLM 540 is prompted with a test plan (e.g., a simulation test plan 112a and/or formal verification plan 112b), the prompt requesting that the LLM 540 generate simulation unit tests 116a and/or formal verification assertions 116b. The output of the LLM 540 in response to the prompt may then be used as the simulation unit tests 116a and/or formal verification assertions 116b in subsequent processing by the system 100.

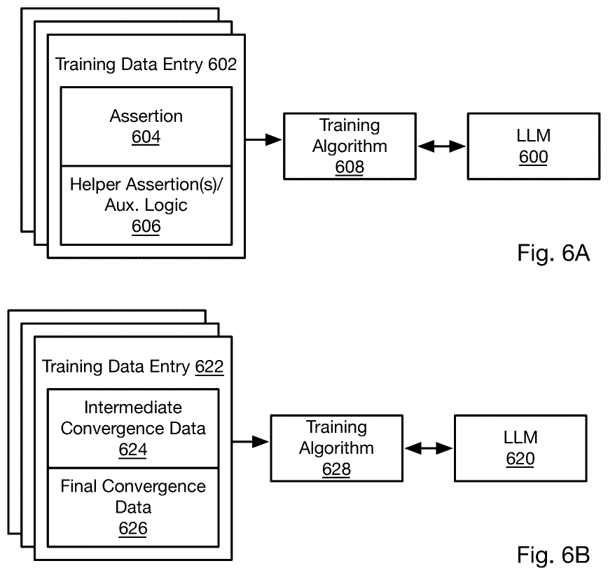

Referring to FIG. 6A, in some embodiments, the test code generation stage 114 may implement additional functionality to facilitate the generation of formal verification assertions 116b. For example, an LLM 600 may be prompted to provide helper assertions or auxiliary logic to facilitate the verification of a more complex assertions such as may be generated by the LLM 540.

The LLM 600 may be trained using training data entries 602. Each training data entry 542 may include, as an input, an assertion 604, e.g., a complex assertion involving multiple variables and complex logical relationships therebetween. The desired output of each training data entry 602 may be one or more helper assertions 606. The desired output may additionally or alternatively include auxiliary logic to facilitate the verification of the assertion 604. The helper assertions 606 and/or auxiliary logic may be written by a human or automatically generated and revised or verified by a human. The helper assertions 606 and/or auxiliary logic may address performance challenges related to state space complexity and assertion convergence. The helper assertions 606 and/or auxiliary logic may specifically target performance improvements for liveness assertions in formal verification.

A training algorithm 608 may prompt the LLM 600 with the input from each training data entry 602, receive an output from the LLM 600 in response to the prompt, compare the output from the LLM 600 with the output from the training data entry 602, and provide feedback to the LLM 600 according to the comparison. The prompt to the LLM 600 may include an instruction to generate helper assertions and/or auxiliary logic and may include an example, e.g., an example assertion and corresponding example helper assertions and/or example auxiliary logic that were generated by a human.

During utilization, the trained LLM 600 is prompted with an assertion, the prompt requesting that the LLM 520 generate one or more helper assertions and/or auxiliary logic. The output of the LLM 600 in response to the prompt may then be used to process the assertion by an EDA tool in order to verify a circuit design.

The system 100 may additionally be configured to use empirical analysis to measure the performance improvements resulting from the use of helper assertions and auxiliary logic.

Referring to FIG. 6B, in another example, an LLM 620, or other machine learning model, may be trained to estimate convergence of the evaluation of an assertion with respect to a circuit design represented by an RTL file 102. The LLM 520 may be trained using training data entries 542 that include, as inputs, intermediate convergence data 624. The intermediate convergence data 624 includes data that is available at some point during the processing of assertion prior to completion of the processing of the assertion, e.g., a final verification or failure decision. The intermediate convergence data 624 may therefore include the assertion, any helper assertions or auxiliary logic, log files from an EDA tool processing the assertion, an elapsed time that the assertion has been processed, the circuit design (e.g., RTL file 102 and/or model 400), or the like. Each training data entry 622 may include, as a desired output, final convergence data 626. The final convergence data 626 may be a record of the final result of actually processing of the assertion, such as a final time of convergence, whether the assertion failed or was successful, whether a timeout condition was reached, or other result.

A training algorithm 628 may prompt the LLM 620 with the input from each training data entry 622, receive an output from the LLM 620 in response to the prompt, compare the output from the LLM 620 with the output from the training data entry 622, and provide feedback to the LLM 620 according to the comparison. The prompt to the LLM 620 may include an instruction to estimate the final result of processing the assertion based on the input.

During utilization, the trained LLM 620 is prompted with intermediate convergence data as defined above, such as may be obtained during the processing of an assertion by an EDA tool. The prompt may request that the LLM 620 estimate final convergence data. The output of the LLM 620 in response to the prompt may then be used to estimate when processing of an assertion will complete or to abort processing of an assertion where the output of the LLM 620 indicates that the assertion will fail or fail to converge.

The system 100 may additionally be configured to analyze formal verification engines of various EDA tools to identify those with better performance. Performance improvements obtained from the use of helper assertions and auxiliary logic may also be measured and reported.

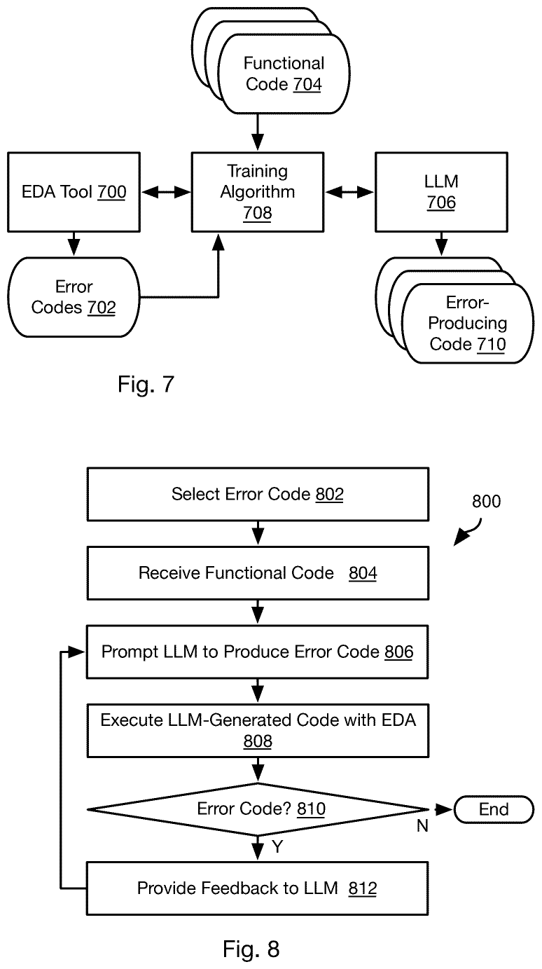

FIG. 7 illustrates an approach for generating training data for an LLM used to implement the repair stage 118. In particular, FIG. 7 illustrates an approach for generating error-producing code (e.g., RTL code) and corresponding functional code that corrects errors present in the error-producing code. As used herein, errors may include syntax errors that would prevent compilation of the error-producing code. Errors may include any error that may be output by an EDA tool based on processing of RTL code. For example, error codes may include any error that may be output by the VERIFIC parser parsing VERILOG or other RTL.

An EDA tool 700 may define a plurality of error codes 702. The error codes 702 may be obtained from documentation of the EDA tool 700, executing commands with respect to the EDA tool 700 to obtain a report of possible error codes, or other approach.

Functional code 704 may be used to train an LLM 706. For example, a training algorithm 708 may train the LLM 706 to convert functional code 704 to generate corresponding error-producing code. In particular, for each error code in the error codes 702, the training algorithm 708 may train the LLM 706 to convert functional code 704 to error-producing code 710 producing that error code.

Referring to FIG. 8, the training algorithm 708 may execute the illustrated method 800 in order to train the LLM 706. The method 800 may include selecting 802 and error code from the error codes 702 (“the selected error code”), receiving 804 functional code 704, e.g., an RTL file. The RTL file of step 804 may be RTL code implementing a simulation test of a DUT. Formal assertions including error-generating assertions, such as an SVA file, may be generated using an LLM trained to perform this task in the same manner as described herein with respect to RTL code.

The method 800 may include prompting 806 the LLM 706 to modify the functional code to obtain error-producing code that generates the selected error code. The prompt of step 806 may include an example including example error-producing code that produces the selected error code and possibly example log data as output by the EDA in response to processing the error-producing code.

Code generated by the LLM 706 in response to the prompt of step 806 may be executed 808 using the EDA tool 700. The result of the execution of step 806 may be evaluated at step 810. If the result of the execution of step 806 is the generation of the selected error code then the method 800 may end with respect to the selected error code. If the result of the execution of step 806 is not the selected error code, then feedback may be provided to the LLM at step 812. The feedback may indicate that the LLM-generated code did not produce the selected error. The feedback may include outputs of the EDA tool 700, such as a log file or outputs to a command line interface.

The method 800 may be repeated for each of the error codes 702 and may be repeated many times for each error code of the error codes 702.

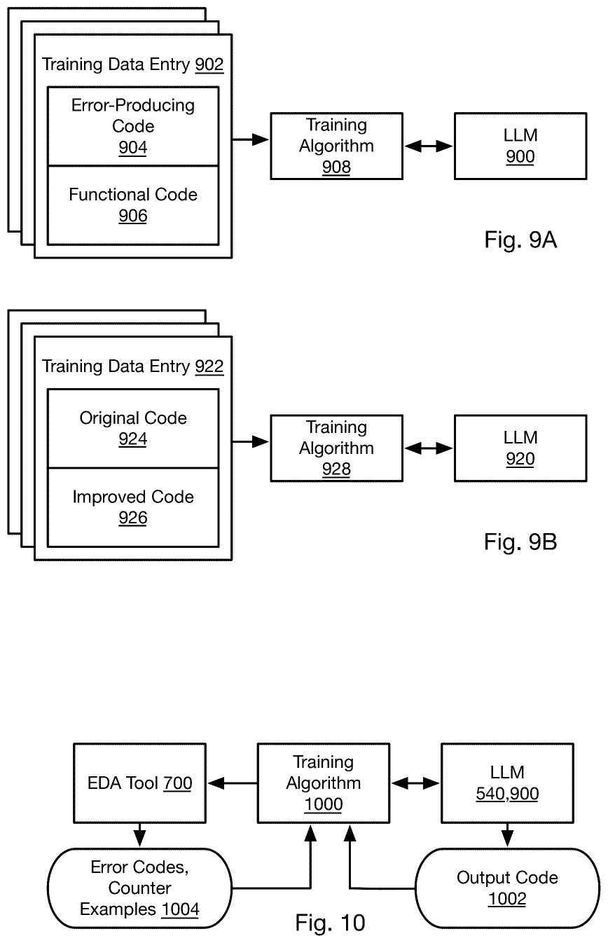

Following training, the LLM 706 may be used to generate many training data entries, such as many thousands of training data entries. For example, for each RTL file of a plurality of RTL files including functional code, the RTL file may be input to the LLM 706 with a prompt to generate an error code of the error codes 702. Each RTL file and the corresponding error-producing code generated by the LLM 706 in response to the prompt may be used as a training data entry as described below with respect to FIG. 9A. The same RTL file may be processed multiple times with prompts including multiple different error codes of the error codes 702 with a training data entry being generated for each time the RTL file is processed.

Referring to FIG. 9A, an LLM 900 may be trained to implement the repair stage 118 using training data entries generated using the LLM 706. In particular, the LLM 900 may be trained using a distillation or transfer learning approach using training data generated using the LLM 706. For example, the LLM 900 may be trained with training data entries 902, each training data entry 902 including, as an input, error-producing code 904 and, as a desired output, functional code 906, where the error-producing code 904 was generated by the LLM 706 from the functional code 906. The training data entries 902 may also include human-generated training data entries 902. The training data entries 902 may include annotations showing corrections to the error-producing code 904.

A training algorithm 908 may prompt the LLM 900 with the input from each training data entry 902, receive an output from the LLM 900 in response to the prompt, compare the output from the LLM 900 with the output from the training data entry 902, and provide feedback to the LLM 900 according to the comparison. The prompt to the LLM 900 may include an instruction to correct the error-producing code 904 of the input. The input may specify the error code generated by the EDA tool 700 in response to processing the error-producing code 904 and the instruction may include an instruction to correct the specific error code generated by the error-producing code 904 of the input. Training of the LLM 900 may be performed using advanced techniques.

During utilization, the trained LLM 900 is prompted with error-producing code and possibly with an error code produced by an EDA tool in response to the error-producing code. The prompt may request that the LLM 900 correct the error-producing code such that the error code will not be generated in response to processing the code generated by the LLM 900 in response to the prompt. The output of the LLM 900 in response to the prompt may then be used as the output of the repair stage 118.

For example, during utilization, test code (e.g., simulation unit tests (RTL) or formal assertions (SVA)) of the test code generation stage 114 may be processed by an EDA tool 700. If the output of the EDA tool 700 from processing the test code includes an error code, the LLM 900 may be used to correct the test code as described above.

Referring to FIG. 9B, an LLM 920 may be trained to process test code, such as simulation unit tests (e.g., RTL files) or formal assertions (e.g., SVA files), in order to correct logical errors, improve performance, improve coverage, or perform other improvements. For example, the LLM 920 may be trained with training data entries 922, each training data entry 922 may include, as an input, original code 924 and, as a desired output, improved code 926, where the improved code is a version of the original code 924 that has been modified to correct a logical or semantic error, improve performance, improve coverage, or is otherwise improved relative to the original code 924. The training data entries 922 may be human generated. The training data entries 922 may include annotations showing corrections to the original code 924.

A training algorithm 928 may prompt the LLM 920 with the input from each training data entry 922, receive an output from the LLM 920 in response to the prompt, compare the output from the LLM 920 with the output from the training data entry 922, and provide feedback to the LLM 920 according to the comparison. The prompt to the LLM 920 may include an instruction to improve the original code 924 of the input and may specify the type of improvement to be performed (correct a semantic or logical error, improve performance, improve coverage, or other improvement).

During utilization, the trained LLM 920 is prompted with original code, such as automatically generated simulation unit tests (e.g. RTL code) or formal assertions (e.g., SVA code) output by the test code generation stage 114 either with or without correction using the LLM 706. The prompt may request that the LLM 920 improve the original code and may specify the type of improvement to perform. The output of the LLM 900 in response to the prompt may then be used as the output of the repair stage 118. The LLM 920 may process code that has been corrected using the LLM 900 or test code output by the test code generation stage 114 that was not found to require correction using the LLM 900.

In some embodiments, a separate LLM 920 is trained to perform each type of improvement such that during utilization the original code is processed by each separate LLM 920 to improve the original code according to each type of improvement. For example, the output of one LLM 920 may be input to another LLM 920 until all of the LLMs 920 have been utilized with the output of the last LLM 920 being the output of the repair stage 118.

Referring to FIG. 10, an LLM 900 may be continually trained during utilization and LLM 540 that is used to generate test code (simulation unit tests (e.g., RTL code) or formal assertions (e.g., SVA code)) may also be trained during utilization. For example, a training algorithm 1000, or other software module, may invoke execution of code 1002 output by the LLM 540,900. The training algorithm 1000 may use outputs 1004 of the EDA tool 700 in response to processing the code 1002 as feedback to the LLM 540, 900. The outputs of the EDA tool 700 may include error codes, counter examples, or other feedback. For example, the outputs of the EDA tool 700 may include outputs from a formal verification engine indicating how to improve performance of a formal verification or of a circuit design itself. The training algorithm 1000 may therefore provide the outputs 1004 to the LLM 540, 900 to enable the LLM 540, 900 to further improve.

FIG. 11 illustrates a method 1100 for repairing code using the LLM 900. The method 1100 may be executed by the repair stage 118. The method 1100 may include inputting 1102 LLM-generated code to an EDA tool 700 and evaluating 1104 whether the LLM-generated code resulted in the EDA tool 700 generating an error code. The LLM-generated code may be code generated by the test code generation stage 114 or previously corrected by the repair stage 118.

If the LLM-generated code is found at step 1104 to have generated at an error code, the method 1100 may include generating, at step 1106, a prompt and submitting the prompt to the LLM 900, the prompt may include the error code, or multiple error codes, resulting from step 1102, the LLM-generated code processed at step 1102, and an instruction to correct the LLM-generated code such that the error code will not occur.

The corrected code is received 1108 from the LLM 900 may be processed as the LLM-generated code at step 1102. The method 1100 may end when no error code is found at step 1104, or a time out occurs.

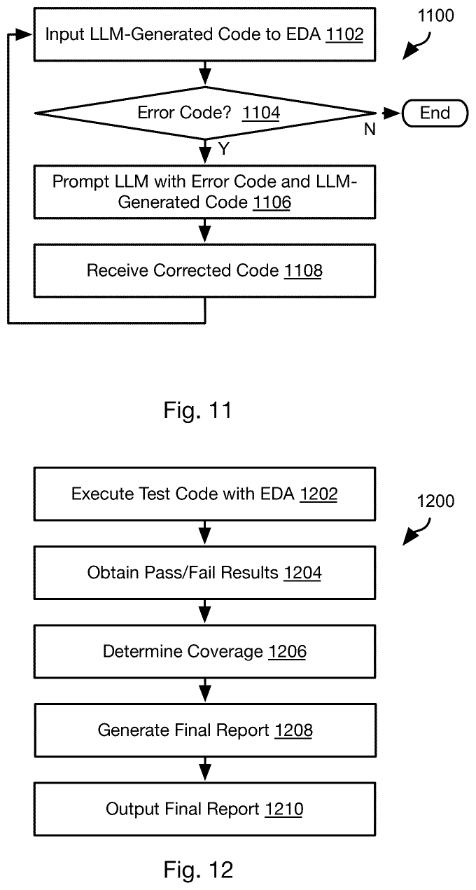

Referring to FIG. 12, the illustrated method 1200 may be executed using the execution and coverage stage 120 of the system 100 to test the circuit design represented by the RTL file 102. The method 1200 may include executing 1202 test code with the EDA tool 700. The test code may be simulation unit tests 116a or formal verification assertions 116b that are generated by the test code generation stage 114 and corrected by the repair stage 118 as needed.

The method 1200 may include obtaining 1204 the results of execution, such as pass/fail results for tests defined by the test code. The method 1200 may include determining 1206 coverage of the test code, such as as reported by the EDA tool 700 or by evaluation of the results output by the EDA tool 700.

The method 1200 may include generating 1208 a final report. The final report may include the pass/fail results, coverage, or other information. The final report may then be output 1210, such as by writing to a log file, transmitting to a device from which the RTL file 102 and specification 104 were received, displaying on a display device, transmitting in an email or other type of message, or using some other type of output.

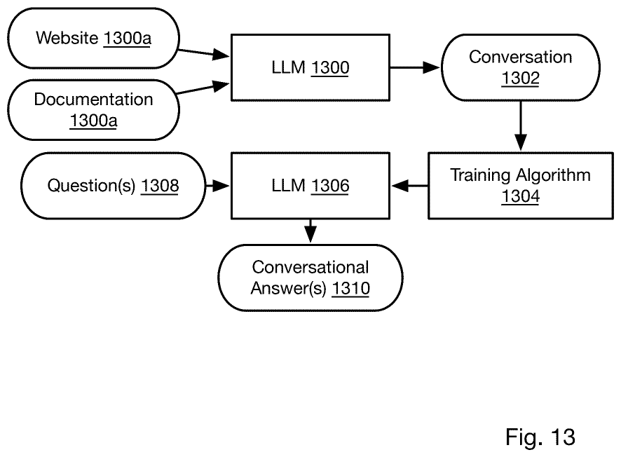

Referring to FIG. 13, in some embodiments, the system 100 or other system may provide a chat function that enables users to ask questions regarding circuit design, RTL, SVA, and/or how to use the EDA tool 700.

Questions and answers may be obtained from various sources 1300a, 1300b. For example, the questions and answers may be derived from information gathered from websites 1300a, such as a website of a vendor providing the EDA tool 700 or a programming language (e.g., RTL or SVA), forums, or other types of websites. Questions and answers may be gathered from documentation 1300b for the EDA tool 700 or a programming language. Questions and answers may be gathered from other sources of information as well, such as text books relating to circuit design or other online resources instructing users regarding circuit design. The information from the various sources 1300a, 1300b may be recast as questions and answers by processing information from the various sources 1300a, 1300b using a general purpose LLM, manually, or using programmatic language processing algorithm. Alternatively, an LLM may be trained to perform this task.

An LLM 1300, such as a general purpose LLM trained to carry on a conversation, may be prompted to convert individual questions and answers or sets of questions and answers into conversations 1302. The conversations may be used by a training algorithm 1304 to train a domain specific LLM 1306 to answer questions in a conversational manner, the questions relating to the EDA tool 700, a programming language, and/or circuit design.

During utilization, a question 1308 may be input to the LLM 1306 as prompt and the LLM 1306 may respond with conversational answers 1310. The LLM 1306 may be trained to carry on a conversation such that responses to a question 1308 may take into account previous questions 1308 and/or answers in a conversation with a source of the question 1308.

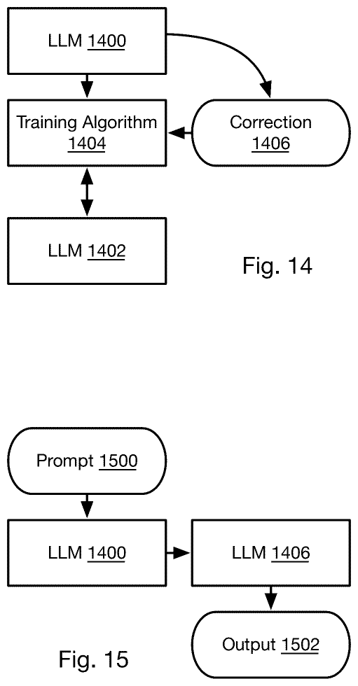

FIGS. 14 to 16 illustrate approaches that may be used to enhance the accuracy of an LLM and generate training data for an LLM according to any of the embodiments disclosed above.

Referring specifically to FIG. 14, in some embodiments, an LLM 1400 may be trained to perform a task as described above and may be used with a correction LLM 1402 trained to correct known errors output by the LLM 1400. For example, the correction LLM 1402 may be trained to correct errors that are output by the LLM 1400 following training of the LLM 1400.

For example, a training algorithm 1404 may receive an output of the LLM 1400 and a correction to the output of the LLM 1400, such as a correction received from a human reviewer. The training algorithm 1404 may additionally receive the prompt received by the LLM 1400 upon which the output of the LLM 1400 was based. The training algorithm 1404 may train the LLM 1402 to implement the correction with respect to the output of the LLM 1400. For example, the LLM 1402 may prompt the LLM 1402 to determine any correction needed for the output of the LLM 1400, receive a response to the prompt from the LLM 1402, compare the response to the correction 1406, and provide feedback to the LLM 1400 according to the comparison. This process may be repeated for many outputs of the LLM 1400 and corresponding corrections 1406. Training of the LLM 1402 may include prompting the LLM 1402 to determine whether correction is needed for correct outputs of the LLM 1400 and affirming responses from the LLM 1402 to such prompts that do not make corrections and providing feedback when correction is incorrectly made by the LLM 1402.

Referring to FIG. 15, during utilization, a prompt 1500 is provided to the LLM 1400, such as a prompt described above as being used during utilization of any of the LLMs described herein. The LLM 1400 outputs a response that is input as part of a prompt to the LLM 1400, e.g., a prompt to the LLM 1400 to correct any errors in the output of the LLM 1400. The LLM 1400 may generate an output 1502 in response to the prompt 1500, which may be the original output of the LLM 1400 or a corrected version thereof. The output 1502 may be used in the same manner as the output an LLM according to any of the embodiments described herein.

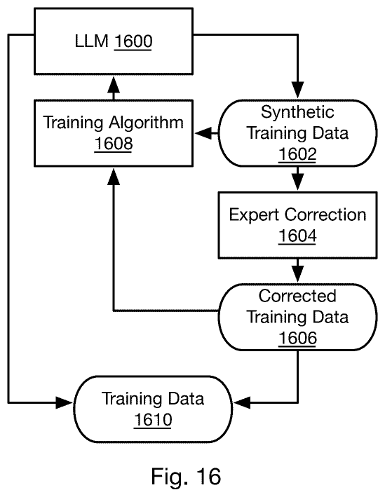

FIG. 16 illustrates an approach for generating synthetic data for training an LLM, such as any of the LLMs described above. In particular, FIG. 16 illustrates an approach for training an LLM 1600 to generate synthetic training data 1602. The LLM 1600 may generate synthetic training data 1602. For example, the LLM 1600 may be prompted to generate synthetic training data, such as a model, test plan, test code, or any of the other data used to train an LLM according to the approaches described above. The synthetic training data 1602 may receive expert correction 1604. For example, the synthetic data may be reviewed by an expert that can revise the synthetic training data 1602 to obtain corrected training data 1606 or confirm that the synthetic training data 1602. The corrected training data 1606 may be used by a training algorithm 1608 to provide feedback to the LLM 1600. For example, an item of corrected training data 1606 may be input along with an item of synthetic training data that was corrected to obtain the corrected training data 1606. A prompt that was used to generate the synthetic training data may also be used by the training algorithm 1608 to provide feedback to the LLM 1600. The corrected training data and synthetic training data generated by the LLM 1600 following training or confirmed by an expert to be correct may provide training data 1610 for training another LLM to perform a task, such as the tasks performed by any of the LLMs described hereinabove.

In the foregoing description, many different LLMs are described. Each LLM described above may be a separate LLM relative to the other LLMs described herein. Alternatively, the functions ascribed to multiple LLMs in the foregoing description may be performed by a single LLM. For example, any two or more of the LLMs 500, 520, 540 may be implemented as a single LLM. LLMs 600, 620 may be implemented as a single LLM or separate LLMs. LLMs 900, 920 may be implemented as a single LLM or separate LLMs.

Any of the LLMs described herein may be subject to a validation process. For example, the validation process may include constructing challenging benchmarks using human-artificial intelligence collaboration. Each LLM may be benchmarked on standard datasets for the task or tasks performed by the LLM. Empirical studies may be conducted to assess the performance of the LLMs. Models may be iteratively improved based on feedback (see, e.g., FIGS. 10 and 16 and corresponding description) and performance metrics.

Some or all of the LLMs described above as being used to implement system 100 may be integrated with existing EDA tools and workflows. The system 100 may additionally include user interfaces and or application programming interfaces (API) to facilitate easy access to the LLMs of the system 100. Operation of the LLMs may be continuously monitored and the LLMs may be updated based on the monitoring to improve performance.

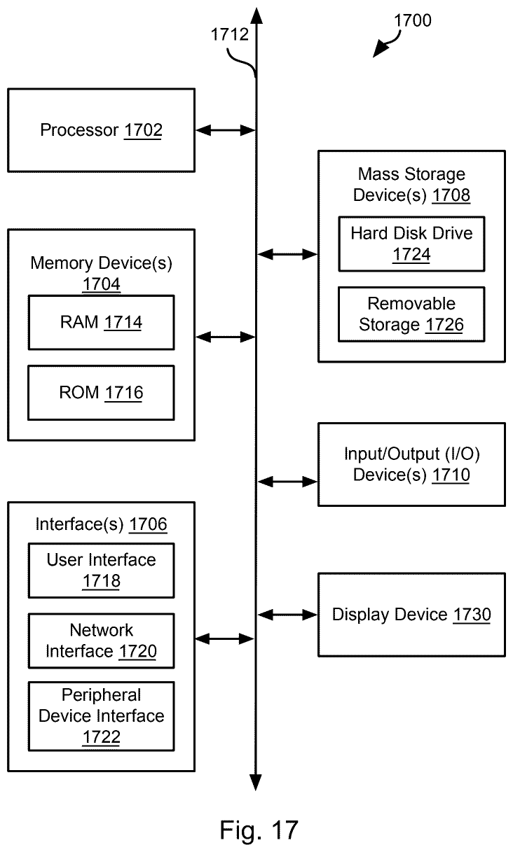

FIG. 17 is a block diagram illustrating an example computing device 1700. Computing device 1700 may be used to perform various procedures, such as those discussed herein. In particular, the system 100 and systems for training LLMs for use in the system 100 may be embodied as a computing device 1700.

Computing device 1700 includes one or more processor(s) 1702, one or more memory device(s) 1704, one or more interface(s) 1706, one or more mass storage device(s) 1708, one or more Input/Output (I/O) device(s) 1710, and a display device 1730 all of which are coupled to a bus 1712. Processor(s) 1702 include one or more processors or controllers that execute instructions stored in memory device(s) 1704 and/or mass storage device(s) 1708. Processor(s) 1702 may also include various types of computer-readable media, such as cache memory. The processor 1702 may be embodied as or further include a graphics processing unit (GPU) including multiple processing cores.

Memory device(s) 1704 include various computer-readable media, such as volatile memory (e.g., random access memory (RAM) 1714) and/or nonvolatile memory (e.g., read-only memory (ROM) 1716). Memory device(s) 1704 may also include rewritable ROM, such as Flash memory.

Mass storage device(s) 1708 include various computer readable media, such as magnetic tapes, magnetic disks, optical disks, solid-state memory (e.g., Flash memory), and so forth. As shown in FIG. 17, a particular mass storage device is a hard disk drive 1724. Various drives may also be included in mass storage device(s) 1708 to enable reading from and/or writing to the various computer readable media. Mass storage device(s) 1708 include removable media 1726 and/or non-removable media.

I/O device(s) 1710 include various devices that allow data and/or other information to be input to or retrieved from computing device 1700. Example I/O device(s) 1710 include cursor control devices, keyboards, keypads, microphones, monitors or other display devices, speakers, printers, network interface cards, modems, lenses, CCDs or other image capture devices, and the like.

Display device 1730 includes any type of device capable of displaying information to one or more users of computing device 1700. Examples of display device 1730 include a monitor, display terminal, video projection device, and the like.

Interface(s) 1706 include various interfaces that allow computing device 1700 to interact with other systems, devices, or computing environments. Example interface(s) 1706 include any number of different network interfaces 1720, such as interfaces to local area networks (LANs), wide area networks (WANs), wireless networks, and the Internet. Other interface(s) include user interface 1718 and peripheral device interface 1722. The interface(s) 1706 may also include one or more peripheral interfaces such as interfaces for printers, pointing devices (mice, track pad, etc.), keyboards, and the like.

Bus 1712 allows processor(s) 1702, memory device(s) 1704, interface(s) 1706, mass storage device(s) 1708, I/O device(s) 1710, and display device 1730 to communicate with one another, as well as other devices or components coupled to bus 1712. Bus 1712 represents one or more of several types of bus structures, such as a system bus, PCI bus, IEEE 1394 bus, USB bus, and so forth.

For purposes of illustration, programs and other executable program components are shown herein as discrete blocks, although it is understood that such programs and components may reside at various times in different storage components of computing device 1700, and are executed by processor(s) 1702. Alternatively, the systems and procedures described herein can be implemented in hardware, or a combination of hardware, software, and/or firmware. For example, one or more application specific integrated circuits (ASICs) can be programmed to carry out one or more of the systems and procedures described herein.

In the above disclosure, reference has been made to the accompanying drawings, which form a part hereof, and in which is shown by way of illustration specific implementations in which the disclosure may be practiced. It is understood that other implementations may be utilized and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Implementations of the systems, devices, and methods disclosed herein may comprise or utilize a special purpose or general-purpose computer including computer hardware, such as, for example, one or more processors and system memory, as discussed herein. Implementations within the scope of the present disclosure may also include physical and other computer-readable media for carrying or storing computer-executable instructions and/or data structures. Such computer-readable media can be any available media that can be accessed by a general purpose or special purpose computer system. Computer-readable media that store computer-executable instructions are computer storage media (devices). Computer-readable media that carry computer-executable instructions are transmission media. Thus, by way of example, and not limitation, implementations of the disclosure can comprise at least two distinctly different kinds of computer-readable media: computer storage media (devices) and transmission media.

Computer storage media (devices) includes RAM, ROM, EEPROM, CD-ROM, solid state drives (“SSDs”) (e.g., based on RAM), Flash memory, phase-change memory (“PCM”), other types of memory, other optical disk storage, magnetic disk storage or other magnetic storage devices, or any other medium which can be used to store desired program code means in the form of computer-executable instructions or data structures and which can be accessed by a general purpose or special purpose computer.

An implementation of the devices, systems, and methods disclosed herein may communicate over a computer network. A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmissions media can include a network and/or data links, which can be used to carry desired program code means in the form of computer-executable instructions or data structures and which can be accessed by a general purpose or special purpose computer. Combinations of the above should also be included within the scope of computer-readable media.

Computer-executable instructions comprise, for example, instructions and data which, when executed at a processor, cause a general purpose computer, special purpose computer, or special purpose processing device to perform a certain function or group of functions. The computer executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the disclosure may be practiced in network computing environments with many types of computer system configurations, including, an in-dash vehicle computer, personal computers, desktop computers, laptop computers, message processors, hand-held devices, multi-processor systems, microprocessor-based or programmable consumer electronics, network PCs, minicomputers, mainframe computers, mobile telephones, PDAs, tablets, pagers, routers, switches, various storage devices, and the like. The disclosure may also be practiced in distributed system environments where local and remote computer systems, which are linked (either by hardwired data links, wireless data links, or by a combination of hardwired and wireless data links) through a network, both perform tasks. In a distributed system environment, program modules may be located in both local and remote memory storage devices.

Further, where appropriate, functions described herein can be performed in one or more of: hardware, software, firmware, digital components, or analog components. For example, one or more application specific integrated circuits (ASICs) can be programmed to carry out one or more of the systems and procedures described herein. Certain terms are used throughout the description and claims to refer to particular system components. As one skilled in the art will appreciate, components may be referred to by different names. This document does not intend to distinguish between components that differ in name, but not function.

These example devices are provided herein purposes of illustration, and are not intended to be limiting. Embodiments of the present disclosure may be implemented in further types of devices, as would be known to persons skilled in the relevant art(s). At least some embodiments of the disclosure have been directed to computer program products comprising such logic (e.g., in the form of software) stored on any computer useable medium. Such software, when executed in one or more data processing devices, causes a device to operate as described herein.

Computer program code for carrying out operations of the present invention may be written in any combination of one or more programming languages, including an object-oriented programming language such as Java, Smalltalk, C++, or the like and conventional procedural programming languages, such as the “C” programming language or similar programming languages. The program code may execute entirely on a computer system as a stand-alone software package, on a stand-alone hardware unit, partly on a remote computer spaced some distance from the computer, or entirely on a remote computer or server. In the latter scenario, the remote computer may be connected to the computer through any type of network, including a local area network (LAN) or a wide area network (WAN), or the connection may be made to an external computer (for example, through the Internet using an Internet Service Provider).

The present invention is described above with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions or code. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a non-transitory computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

While various embodiments of the present disclosure have been described above, it should be understood that they have been presented by way of example only, and not limitation. It will be apparent to persons skilled in the relevant art that various changes in form and detail can be made therein without departing from the spirit and scope of the disclosure. Thus, the breadth and scope of the present disclosure should not be limited by any of the above-described exemplary embodiments, but should be defined only in accordance with the following claims and their equivalents. The foregoing description has been presented for the purposes of illustration and description. It is not intended to be exhaustive or to limit the disclosure to the precise form disclosed. Many modifications and variations are possible in light of the above teaching. Further, it should be noted that any or all of the aforementioned alternate implementations may be used in any combination desired to form additional hybrid implementations of the disclosure.

What is claimed is:

1. A method generating training data comprising:
receiving, by a computer system, a plurality of error codes for an electronic design automation (EDA) tool;
generating a plurality of training data entries by, for each training data entry:
prompting a first large language model (LLM) to modify functional code to generate error-producing code that will result in an error code of the plurality of error codes when processed by the EDA tool;
using the error-producing code as an input of the each training data entry; and
using the functional code as a desired output of the each training data entry; and
training, by the computer system, a second LLM to correct errors, with the plurality of training data entries.

2. The method of claim 1, wherein the EDA tool includes a parser.

3. The method of claim 1, wherein the functional code is a simulation unit test for a device under test (DUT) according to a circuit design.

4. The method of claim 3, wherein the functional code is VERILOG code.

5. The method of claim 1, wherein the functional code is a formal assertion for verifying a circuit design.

6. The method of claim 5, wherein the functional code is system VERILOG assertion (SVA).

7. The method of claim 1, wherein the plurality of training data entries are a plurality of first training data entries, the method further comprising:
receiving, by the computer system, a plurality of second training data entries, each second training data entry including:
an input including original code; and
a desired output including an improved version of the original code; and
training, by the computer system, a third LLM to perform code improvement using the plurality of second training data entries.

8. The method of claim 7, wherein the improved version of the original code has improved performance relative to the original code.

9. The method of claim 8, wherein the improved version of the original code is test code having improved coverage of a circuit design relative to the original code.

10. The method of claim 1, wherein the plurality of training data entries are a plurality of first training data entries, the method further comprising:
receiving, by the computer system, a plurality of second training data entries, each second training data entry including:
an input including a formal assertion for verifying a circuit design; and
a desired output including at least one of helper assertions and auxiliary logic to facilitate processing of the formal assertion by an electronic design automation (EDA) tool; and
training, by the computer system, a third LLM using the plurality of second training data entries.

11. A method for correcting verification code comprising:
receiving, by a computer system, verification code for verifying a circuit design by an electronic design automation (EDA) tool;
submitting, by the computer system, a prompt to an LLM to correct the verification code; and
receiving, by the computer system, corrected code from the LLM in response to the prompt.

12. The method of claim 11, further comprising:
receiving, by the computer system, an error code from the EDA tool responsive to processing the verification code; and
including the error code in the prompt; and
wherein the corrected code is configured such that the EDA tool does not generate the error code when processing the corrected code.

13. The method of claim 11, wherein the EDA tool is a VERIFIC parser.

14. The method of claim 11, wherein the verification code is a simulation unit test for a device under test (DUT) according to the circuit design.

15. The method of claim 14, wherein the verification code is VERILOG code.

16. The method of claim 11, wherein the verification code is a formal assertion for verifying the circuit design.

17. The method of claim 16, wherein the verification code is system VERILOG assertion (SVA).

18. The method of claim 11, wherein the LLM is a first LLM, the method further comprising processing the corrected code using a second LLM to obtain at least one of auxiliary logic and helper assertions to facilitate processing of the corrected code.

19. The method of claim 11, wherein the LLM is a first LLM, the method further comprising processing the corrected code using a second LLM to obtain improved code having improved performance relative to the corrected code.

20. The method of claim 11, wherein the LLM is a first LLM, the method further comprising processing the corrected code using a second LLM to obtain improved code having improved coverage the circuit design relative to the corrected code.
